(19) United States
(12) Patent Application Publication
(10) Pub. No.: US 2010/0006964 A1
(43) Pub. Date: Jan. 14, 2010

(54) BACKSIDE ILLUMINATED IMAGE SENSOR HAVING BIASED CONDUCTIVE LAYER FOR INCREASED QUANTUM EFFICIENCY

(76) Inventors: Shenlin Chen, Rochester, NY (US); Robert M. Guidash, Rochester, NY (US)

Correspondence Address: Pedro P. Hernandez;Patent Legal Staff, Eastman Kodak Company, 343 State Street, Rochester, NY, 14650-2201, US

(21) Appl. No.: 12/170,502

(22) Filed: Jul. 10, 2008

(51) Int. Cl. H01L 31/00; H01L 21/00

(52) U.S. Cl. 257/432; 438/69; 257/E31.001; 257/E21.001

(57) ABSTRACT

A backside illuminated image sensor includes a sensor layer comprising a plurality of photosensitive elements of the pixel array, a circuit layer comprising circuitry associated with the pixel array, a conductive layer formed on a backside surface of the sensor layer, and one or more conductive contacts configured to couple the conductive layer to a bias source in the circuit layer. The biased conductive layer produces an electric field across the photosensitive elements of the pixel array that facilitates charge carrier collection and reduces crosstalk between adjacent photosensitive elements, thereby providing improved quantum efficiency in the image sensor. The image sensor may be implemented in a digital camera or other type of digital imaging device.

### FIELD OF THE INVENTION

The present invention relates generally to electronic image sensors for use in digital cameras and other types of imaging devices, and more particularly to processing techniques for use in forming backside illuminated image sensors.

### BACKGROUND OF THE INVENTION

A typical electronic image sensor comprises a number of light sensitive picture elements (“pixels”) arranged in a two-dimensional array. Such an image sensor may be configured to produce a color image by forming an appropriate color filter array (CFA) over the pixels. Examples of image sensors of this type are disclosed in U.S. Patent Application Publication No. 2007/0024931, entitled “Image Sensor with Improved Light Sensitivity,” which is incorporated by reference herein.

As is well known, an image sensor may be implemented using complementary metal-oxide-semiconductor (CMOS) circuitry. In such an arrangement, each pixel typically comprises a photodiode and other circuitry elements that are formed in a silicon sensor layer on a silicon substrate. One or more dielectric layers are usually formed above the silicon sensor layer and may incorporate additional circuitry elements as well as multiple levels of metallization used to form interconnects. The side of the image sensor on which the dielectric layers and associated levels of metallization are formed is commonly referred to as the frontside, while the side having the silicon substrate is referred to as the backside.

In a frontside illuminated image sensor, light from a subject scene is incident on the frontside of the image sensor, and the silicon substrate is relatively thick. However, the presence of metallization level interconnects and various other features associated with the dielectric layers on the frontside of the image sensor can adversely impact the fill factor and quantum efficiency of the image sensor.

A backside illuminated image sensor addresses the fill factor and quantum efficiency issues associated with the frontside dielectric layers by thinning or removing the thick silicon substrate and arranging the image sensor such that light from a subject scene is incident on the backside of the image sensor. Thus, the incident light is no longer impacted by metallization level interconnects and other features of the dielectric layers, and fill factor and quantum efficiency are improved.

However, additional performance improvements are still needed in backside illuminated image sensors. For example, in backside illuminated image sensors that are formed utilizing a silicon-on-insulator (SOI) image sensor wafer, charge carriers generated in the sensor layer from incident light may recombine in substantial numbers before being collected by associated circuitry. Such carrier recombination limits the level of quantum efficiency that can be achieved in the backside illuminated image sensor. This is particularly true for shorter wavelength portions of the incident light spectrum, such as blue light. Crosstalk between adjacent photodiodes can also contribute to the carrier recombination problem.

Accordingly, a need exists for a backside illuminated image sensor that exhibits reduced carrier recombination and crosstalk, particularly when formed from an SOI image sensor wafer.

### SUMMARY OF THE INVENTION

In an illustrative embodiment, a backside illuminated image sensor comprises a biased conductive layer formed on a backside surface of a sensor layer. The image sensor exhibits reduced carrier recombination and crosstalk, and thus higher quantum efficiency, than a conventional backside illuminated image sensor.

In accordance with one aspect of the invention, a process of forming a backside illuminated image sensor is provided. The image sensor includes a sensor layer comprising a plurality of photosensitive elements of a pixel array, and a circuit layer comprising circuitry associated with the pixel array. The process includes the steps of forming a conductive layer on a backside surface of the sensor layer, and coupling the conductive layer through one or more conductive contacts to a bias source in the circuit layer. The conductive layer when biased by the bias source produces an electric field across the photosensitive elements of the pixel array that facilitates charge carrier collection and reduces crosstalk between adjacent photosensitive elements, thereby providing improved quantum efficiency in the image sensor.

The conductive layer in one embodiment may comprise, for example, a transparent conductive film patterned to include an array of interconnected conductive elements overlying respective ones of the photosensitive elements of the pixel array. The conductive elements may have a quadrilateral shape in a plan view and may be arranged in rows and columns, with the conductive elements of a given one of the rows being interconnected with one another and with a column conductor that is common to all of the rows. The transparent conductive film may be formed from a material comprising a combination of indium, tin and oxide.

The conductive layer in another embodiment may comprise a first semiconductor layer of a first conductivity type. In such an arrangement, the image sensor may further comprise a second semiconductor layer of the first conductivity type arranged on a frontside surface of the sensor layer, and the sensor layer may comprise an implant layer of a second conductivity type arranged between the first and second semiconductor layers of the first conductivity type.

The bias source of the circuit layer may comprise, for example, a charge pump or other bias voltage source of the image sensor. Application of a bias voltage from the bias voltage source to the conductive layer formed on the backside surface of the sensor layer produces the above-noted electric field across the plurality of photosensitive elements.

In accordance with another aspect of the invention, a backside illuminated image sensor includes a sensor layer comprising a plurality of photosensitive elements of the pixel array, a circuit layer comprising circuitry associated with the pixel array, a conductive layer formed on a backside surface of the sensor layer, and one or more conductive contacts configured to couple the conductive layer to a bias source in the circuit layer.

A backside illuminated image sensor in accordance with the invention may be advantageously implemented in a digital camera or other type of imaging device. The image sensor provides improved performance through reductions in carrier recombination and crosstalk, and thus higher quantum efficiency, even for blue light portions of the incident light spectrum.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1 is a block diagram of a digital camera having a backside illuminated image sensor configured in accordance with an illustrative embodiment of the invention;

FIG. 2 is a cross-sectional view showing a portion of a backside illuminated image sensor in which a biased conductive layer may be implemented in an illustrative embodiment of the invention;

FIG. 3 is a cross-sectional view showing a portion of a backside illuminated image sensor having a biased conductive layer in a first illustrative embodiment of the invention;

FIG. 4 is a cross-sectional view showing a portion of a backside illuminated image sensor having a biased conductive layer in a second illustrative embodiment of the invention;

FIG. 5 is a plan view of one possible implementation of a patterned transparent conductive film for use as the biased conductive layer in the backside illuminated image sensor of FIG. 3; and

FIG. 6 is a plan view of an image sensor wafer comprising multiple image sensors of the type illustrated in FIG. 3 or 4.

### DETAILED DESCRIPTION OF THE INVENTION

The present invention will be illustrated herein in conjunction with particular embodiments of digital cameras, backside illuminated image sensors, and processing techniques for forming such image sensors. It should be understood, however, that these illustrative arrangements are presented by way of example only, and should not be viewed as limiting the scope of the invention in any way. Those skilled in the art will recognize that the disclosed arrangements can be adapted in a straightforward manner for use with a wide variety of other types of imaging devices and image sensors.

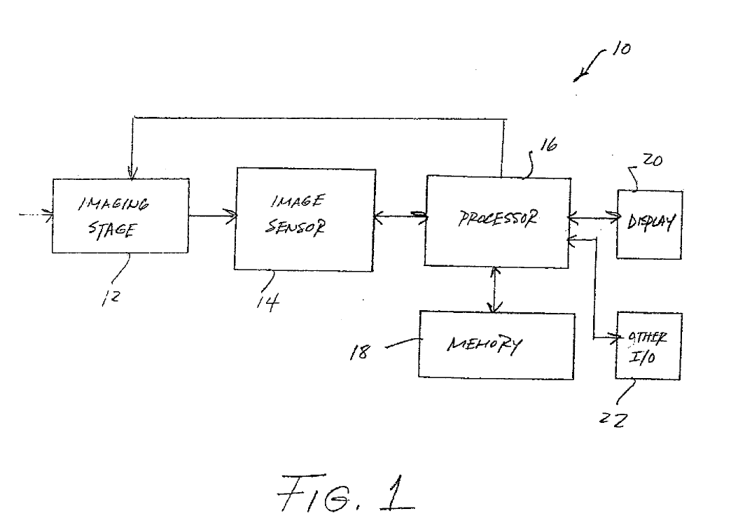

FIG. 1 shows a digital camera 10 in an illustrative embodiment of the invention. In the digital camera, light from a subject scene is input to an imaging stage 12. The imaging stage may comprise conventional elements such as a lens, a neutral density filter, an iris and a shutter. The light is focused by the imaging stage 12 to form an image on an image sensor 14, which converts the incident light to electrical signals. The digital camera 10 further includes a processor 16, a memory 18, a display 20, and one or more additional input/output (I/O) elements 22.

Although shown as separate elements in the embodiment of FIG. 1, the imaging stage 12 may be integrated with the image sensor 14, and possibly one or more additional elements of the digital camera 10, to form a compact camera module.

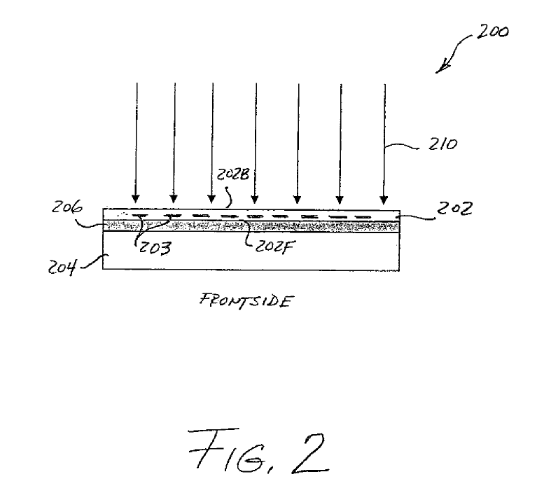

The image sensor 14 is assumed in the present embodiment to be a CMOS image sensor, although other types of image sensors may be used in implementing the invention. More particularly, the image sensor 14 comprises a backside illuminated image sensor that includes a biased conductive layer formed on a backside surface of a sensor layer, as will be described below in conjunction with FIGS. 2 through 5. The image sensor generally comprises a pixel array having a plurality of pixels arranged in rows and columns and may include additional circuitry associated with sampling and readout of the pixel array, such as signal generation circuitry, signal processing circuitry, row and column selection circuitry, etc. The signal generation circuitry may comprise, for example, an analog signal processor for processing analog signals read out from the pixel array and an analog-to-digital converter for converting such signals to a digital form. These and other types of circuitry suitable for use in the digital camera 10 are well known to those skilled in the art and will therefore not be described in detail herein. Portions of the sampling and readout circuitry may be arranged external to the image sensor, or formed integrally with the pixel array, for example, on a common integrated circuit with photodiodes and other elements of the pixel array.

The image sensor 14 will typically be implemented as a color image sensor having an associated CFA pattern. Examples of CFA patterns that may be used with the image sensor 14 include those described in the above-cited U.S. Patent Application Publication No. 2007/0024931, although other CFA patterns may be used in other embodiments of the invention. As another example, a conventional Bayer pattern may be used, as disclosed in U.S. Pat. No. 3,971,065, entitled “Color Imaging Array,” which is incorporated by reference herein.

The processor 16 may comprise, for example, a microprocessor, a central processing unit (CPU), an application-specific integrated circuit (ASIC), a digital signal processor (DSP), or other processing device, or combinations of multiple such devices. Various elements of the imaging stage 12 and the image sensor 14 may be controlled by timing signals or other signals supplied from the processor 16.

The memory 18 may comprise any type of memory, such as, for example, random access memory (RAM), read-only memory (ROM), Flash memory, disk-based memory, removable memory, or other types of storage elements, in any combination.

Functionality associated with sampling and readout of the pixel array and the processing of corresponding image data may be implemented at least in part in the form of software that is stored in memory 18 and executed by processor 16.

A given image captured by the image sensor 14 may be stored by the processor 16 in memory 18 and presented on display 20. The display 20 is typically an active matrix color liquid crystal display (LCD), although other types of displays may be used. The additional I/O elements 22 may comprise, for example, various on-screen controls, buttons or other user interfaces, network interfaces, memory card interfaces, etc.

Additional details regarding the operation of a digital camera of the type shown in FIG. 1 can be found, for example, in the above-cited U.S. Patent Application Publication No. 2007/0024931.

It is to be appreciated that the digital camera as shown in FIG. 1 may comprise additional or alternative elements of a type known to those skilled in the art. Elements not specifically shown or described herein may be selected from those known in the art. As noted previously, the present invention may be implemented in a wide variety of other types of digital cameras or imaging devices. Also, as mentioned above, certain aspects of the embodiments described herein may be implemented at least in part in the form of software executed by one or more processing elements of an imaging device. Such software can be implemented in a straightforward manner given the teachings provided herein, as will be appreciated by those skilled in the art.

The image sensor 14 may be fabricated on a silicon substrate or other type of substrate. In a typical CMOS image sensor, each pixel of the pixel array includes a photodiode and associated circuitry for measuring the light level at that pixel. Such circuitry may comprise, for example, transfer gates, reset transistors, select transistors, output transistors, and other elements, configured in a well-known conventional manner.

As indicated above, FIGS. 2 through 5 illustrate the manner in which image sensor 14 may be configured to include a biased conductive layer formed on a backside surface of a sensor layer in illustrative embodiments of the present invention. It should be noted that these figures are simplified in order to clearly illustrate various aspects of the present invention, and are not necessarily drawn to scale. A given embodiment may include a variety of other features or elements that are not explicitly illustrated but would be familiar to one skilled in the art as being commonly associated with image sensors of the general type described.

FIG. 2 shows an image sensor 200 that may be modified to incorporate a biased conductive layer for improving quantum efficiency. The image sensor includes a sensor layer 202 comprising a plurality of photosensitive elements 203 of the pixel array, a circuit layer 204 comprising analog circuitry associated with the pixel array, and an insulating layer 206 arranged between the sensor layer and the circuit layer. The photosensitive elements are typically photodiodes, although other types of photosensitive elements may be used. The pixel array in this example is an active pixel array, that is, a pixel array that includes active pixel circuitry in addition to the photosensitive elements 203. The insulating layer 202 may comprise, for example, an interlayer dielectric (ILD) formed of oxide or other suitable insulating material. The circuit layer 204 may comprise, in addition to the above-noted analog circuitry, an intermetal dielectric (IMD) that separates multiple levels of metallization. The ILD and IMD are illustrative examples of what are more generally referred to herein as dielectric layers.

The image sensor 200 is a backside illuminated image sensor, in that light from a subject scene is incident on the backside of the image sensor, as indicated by the lines 210. The side opposite the backside is labeled as the frontside in the figure. The terms “frontside” and “backside” will be used herein to denote particular sides of an image sensor wafer or an image sensor formed from such a wafer, as well as sides of particular layers of the image sensor wafer or corresponding image sensor. For example, the sensor layer 202 has a frontside surface 202F and a backside surface 202B.

It should be noted that terms such as “on” or “over” when used in conjunction with layers of an image sensor wafer or corresponding image sensor are intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

The image sensor 200 illustrated in FIG. 2 is an example of an image sensor formed from a silicon-on-insulator (SOI) wafer. Such a wafer generally comprises a silicon substrate, a buried oxide (BOX) layer formed over the substrate, and a silicon sensor layer formed over the oxide layer. The thickness of the silicon sensor layer may be approximately 1 to 6 micrometers (μm), and the thickness of the buried oxide layer may be approximately 0.1 to 0.5 μm, although other thicknesses may be used. The silicon substrate is typically substantially thicker than the sensor layer or buried oxide layer. Alternative embodiments of the invention may utilize other types of wafers to form backside illuminated image sensors, such as, for example, epitaxial wafers or bulk semiconductor wafers that do not include a buried oxide layer, although an SOI wafer generally provides a smoother surface for backside processing.

In the process of forming the image sensor, the substrate is typically removed, leaving the buried oxide layer and the sensor layer. Thus, although not expressly shown in FIG. 2, at least a portion of the buried oxide layer may remain on the backside surface 202B of the sensor layer 202. In other embodiments, the buried oxide layer may be removed in its entirety.

The circuit layer 204 may be formed using a separate wafer that is subsequently bonded to an SOI wafer in which the sensor layer 202 is formed. Alternatively, a single SOI wafer or other type of wafer may be used to form both the sensor and the circuit layers. Also, the insulating layer 206 may be eliminated in a given embodiment of the invention.

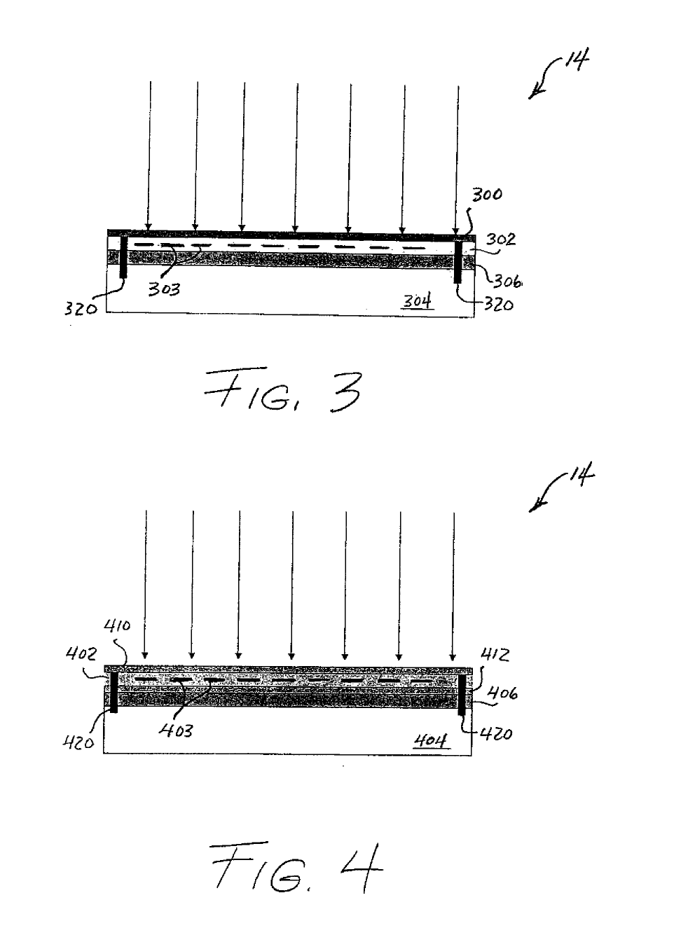

FIG. 3 shows the image sensor 14 in a first illustrative embodiment of the invention. The image sensor 14 corresponds generally to the image sensor 200 as described in conjunction with FIG. 2, but further includes a biased conductive layer 300 formed on a backside surface of a sensor layer 302, as will now be described. The image sensor 14 as shown in FIG. 3 includes an active pixel array in the sensor layer 302, although other types of pixel arrays may be used in alternative embodiments. The pixel array comprises a plurality of photosensitive elements 303, which as noted above are typically implemented as photodiodes. The image sensor further comprises a circuit layer 304 comprising circuitry associated with the pixel array, and an insulating layer 306 arranged between the sensor layer and the circuit layer.

The conductive layer 300 is formed on a backside surface of the sensor layer 302, and is coupled to the circuit layer 304 via metal contacts 320 as shown. More specifically, the metal contacts are configured to couple the conductive layer to a bias source in the circuit layer. This bias source is not explicitly shown in the figure, but may comprise, for example, a bias voltage source such as a charge pump or other type of bias voltage source. Application of a bias voltage from the bias voltage source of the circuit layer 304 to the conductive layer 300 produces an electric field across the photosensitive elements 303 of the pixel array that facilitates charge carrier collection and reduces crosstalk between adjacent photosensitive elements, thereby providing improved quantum efficiency in the image sensor 14. Significant improvement in quantum efficiency is advantageously achieved even for shorter wavelength portions of the incident light spectrum, including blue light. The applied bias voltage may be a positive or negative voltage having a magnitude less than or equal to approximately three volts, but the particular value used in a given embodiment will generally depend upon the pixel design.

The conductive layer 300 in this illustrative embodiment more particularly comprises a patterned transparent conductive film. The patterned transparent conductive film is patterned to comprise an array of interconnected conductive elements overlying respective ones of the photosensitive elements 303 of the pixel array. A more particular example of such an array of interconnected conductive elements will be described below in conjunction with FIG. 5. The metal contacts 320 may be formed using conventional techniques and materials that are well known to those skilled in the art.

The patterned transparent conductive film of conductive layer 300 may be formed, for example, by deposition or sputtering of a material comprising a combination of indium, tin and oxide, also referred to herein as an ITO film, followed by conventional lithographic patterning, although other materials and formation processes may be used in other embodiments. The thickness of the patterned transparent conductive film may be on the order of 0.01 μm to 10 μm, again depending upon the pixel design.

As a more particular example, the patterned transparent conductive film of conductive layer 300 may comprise a mixture of indium oxide (In₂O₃) and tin oxide (SnO₂), such as 90% In₂O₃ and 10% SnO₂ by weight. Again, different combinations may be used in alternative embodiments.

The conductive layer 300 is generally formed on the backside surface of the sensor layer 302 of the image sensor 14 prior to formation of CFA elements and corresponding microlenses. Thus, the conductive layer 300 will underlie the CFA layer of the image sensor, although the latter layer is omitted from the diagrams in FIGS. 2 through 4 for clarity and simplicity of illustration.

As indicated above, the contacts 320 may be formed from a suitable conductive metal. Other structures that may be used to form at least portions of the contacts include, for example, a layered structure comprising the above-described ITO, titanium nitride (TiN) and tungsten (W), or a layered structure comprising aluminum (Al) and TiN. The TiN in these examples may have a thickness on the order of several hundred Angstroms, while the ITO, W and Al may have thicknesses on the order of several thousand Angstroms.

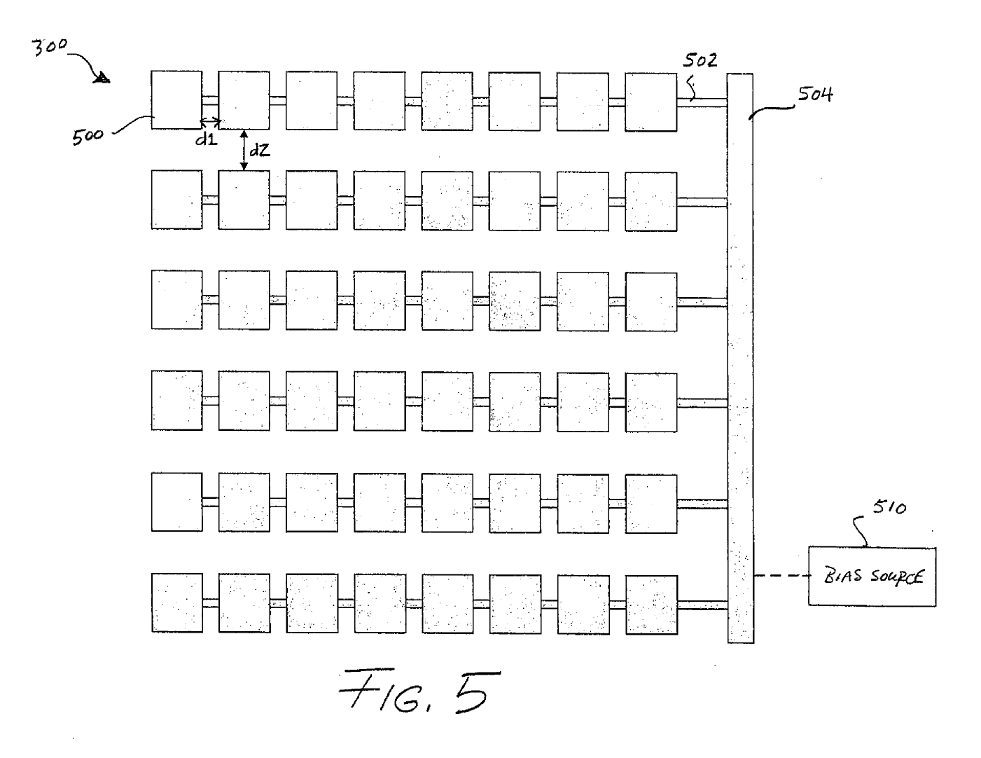

FIG. 4 shows the image sensor 14 in another illustrative embodiment. This embodiment differs from the FIG. 3 embodiment in the configuration of the conductive layer and the manner in which the conductive layer is formed. The image sensor 14 in the FIG. 4 embodiment includes a sensor layer 402 comprising a plurality of photosensitive elements 403 of the pixel array, a circuit layer 404 comprising analog circuitry associated with the pixel array, and an insulating layer 406 arranged between the sensor layer and the circuit layer.

The conductive layer in this embodiment comprises a first semiconductor layer 410 of a first conductivity type, formed on a backside surface of the sensor layer 402. The first semiconductor layer 410 more specifically comprises a p-type semiconductor layer, which may be a boron-doped silicon layer, although other types of dopants and materials may be used. The image sensor 14 further comprises a second semiconductor layer 412 of the first conductivity type arranged on a frontside surface of the sensor layer 402. The sensor layer in this embodiment also includes an implant layer of a second conductivity type, that is, an n-type implant layer in this embodiment, arranged between the first and second p-type layers 410 and 412. The n-type implant layer may more specifically comprise a phosphorous-doped silicon layer, although as indicated above other types of dopants and materials may be used. The particular dopant concentrations used for the p-type layers 410 and 412 and the intervening n-type implant layer will generally vary depending upon the pixel design, and conventional dopant concentrations associated with such designs may be used in a given embodiment.

The two p-type layers 410 and 412 and the n-type implant layer provide a PNP structure that is coupled via metal contacts 420 to a bias source in the circuit layer 404. This type of structure is generally utilized in an embodiment in which the sensor layer comprises p-type photodiodes and p-type MOS (PMOS) transistors. In such an arrangement, the photodiodes and the transistors may be formed in an n-well region of the sensor layer.

As in the FIG. 3 embodiment, a bias voltage applied to the conductive layer comprising p-type semiconductor layer 410 via the metal contacts 420 produces an electric field across the photosensitive elements 403 of the pixel array that facilitates charge carrier collection and reduces crosstalk between adjacent photosensitive elements, thereby providing improved quantum efficiency in the image sensor 14. Again, bias voltages having a magnitude less than about three volts will typically be used.

The bias voltage applied via the metal contact 420 is applied only to the upper p-type layer 410. For this exemplary PNP structure, a negative bias is usually applied to the layer 410 in order to provide the desired enhancement in quantum efficiency.

The thicknesses of the p-type layers 410, 412 and the n-type implant layer may be on the order of 0.01 μm to 10 μm, although other thicknesses may be used.

An alternative implementation of the FIG. 4 embodiment may replace the PNP structure with an NPN structure in which the semiconductor layers 410, 412 are n-type layers and the implant layer is a p-type layer. Such an implementation is appropriate in an embodiment in which the sensor layer comprises n-type photodiodes and n-type MOS (NMOS) transistors. In such an arrangement, the photodiodes and the transistors may be formed in a p-well region of the sensor layer. A positive bias voltage may be applied to the uppermost n-type layer for this type of NPN structure.

FIG. 5 shows one possible implementation of a patterned transparent conductive film for use as the biased conductive layer 300 in the backside illuminated image sensor 14 of FIG. 3. The view shown in FIG. 5 is a plan view looking down on the backside of image sensor 14 in the direction of the incident light. In this example, the transparent conductive film is patterned to comprise an array of interconnected conductive elements 500 overlying respective ones of the photosensitive elements 303 of the pixel array. More specifically, the conductive elements 500 have a quadrilateral shape in the plan view and are arranged in rows and columns. The conductive elements of a given row are interconnected with one another via one or more row conductors 502 that are coupled to a column conductor 504 that is common to all of the rows. The distances d₁ and d₂ between adjacent conductive elements 500 maybe approximately 0.01 μm to 2.0 μm, again depending upon the design of the pixels of the active pixel array, such as the size and shape of the pixels.

The patterned transparent conductive film of conductive layer 300 as illustrated in FIG. 5 is coupled to a bias source 510 formed in the circuit layer 304, as previously indicated.

Numerous alternative patterns may be used, for example, with different conductive element shapes and different row and column interconnects. Also, an unpatterned transparent conductive film may be used in an alternative embodiment. That is, the conductive layer 300 may comprise a single continuous transparent conductive layer overlying the pixel array of the image sensor layer. However, an advantage of a patterned conductive layer 300 of the type shown in FIG. 5 is that regions of the pixel array between adjacent photosensitive elements will have a lower electric field. This tends to further reduce crosstalk between adjacent pixels, and thereby provides additional improvements in quantum efficiency relative to use of an unpatterned transparent conductive layer.

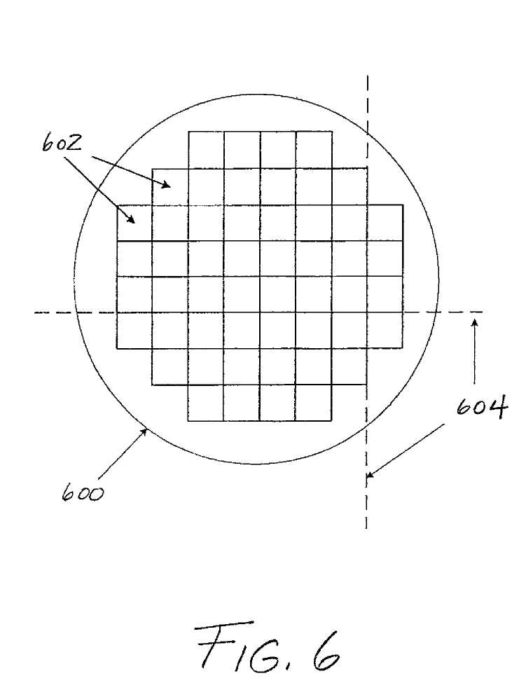

FIG. 6 shows an image sensor wafer 600 that may be used to form a plurality of image sensors of the type shown in FIG. 3 or 4. Multiple image sensors 602 are formed through wafer level processing of the image sensor wafer 600 and then separated from one another by dicing the wafer along dicing lines 604. Each of the image sensors 602 may be an image sensor 14 as illustrated in FIG. 3 or 4.

The invention has been described in detail with particular reference to certain illustrative embodiments thereof, but it will be understood that variations and modifications can be effected within the scope of the invention as set forth in the appended claims. For example, other types of image sensors and digital imaging devices may be used, using alternative types of materials, wafers, layers, conductors, process steps, etc. Thus, a given image sensor need not have an insulating layer between the sensor layer and the circuit layer, and a single SOI wafer or other type of wafer may be used to form both the sensor layer and the circuit layer. These and other alternative embodiments will be readily apparent to those skilled in the art.

### Parts List

10 digital camera
12 imaging stage
14 backside illuminated image sensor
16 processor
18 memory
20 display
22 input/output (I/O) elements
200 image sensor
202 sensor layer
202B sensor layer backside surface
202F sensor layer frontside surface
203 photosensitive elements
204 circuit layer
206 insulating layer
210 incident light
300 biased conductive layer
302 sensor layer
303 photosensitive elements
304 circuit layer
306 insulating layer
320 contacts
402 sensor layer
403 photosensitive elements
404 circuit layer
406 insulating layer
410,412 semiconductor layers
420 contacts
500 conductive element
502 row conductor
504 column conductor
510 bias source
600 image sensor wafer
602 image sensors
604 dicing lines

1. A method of forming an image sensor having a pixel array configured for backside illumination, the image sensor including a sensor layer comprising a plurality of photosensitive elements of the pixel array, and a circuit layer comprising circuitry associated with the pixel array, the method comprising the steps of:
forming a conductive layer on a backside surface of the sensor layer; and
coupling the conductive layer through one or more conductive contacts to a bias source in the circuit layer.

2. The method of claim 1 wherein the step of forming a conductive layer comprises forming the conductive layer as a transparent conductive film.

3. The method of claim 2 wherein the step of forming a conductive layer as a transparent conductive film further comprises patterning the transparent conductive film such that the film comprises an array of interconnected conductive elements overlying respective ones of the photosensitive elements of the pixel array.

4. The method of claim 3 wherein the conductive elements have a quadrilateral shape in a plan view and are arranged in rows and columns, with the conductive elements of a given one of the rows being interconnected with one another and with a column conductor that is common to all of the rows.

5. The method of claim 2 wherein the step of forming a conductive layer as a transparent conductive film further comprises forming the transparent conductive film from a material comprising a combination of indium, tin and oxide.

6. The method of claim 1 wherein the step of forming a conductive layer further comprises forming the conductive layer as a first semiconductor layer of a first conductivity type.

7. The method of claim 6 wherein a second semiconductor layer of the first conductivity type is formed on a frontside surface of the sensor layer and wherein the sensor layer further comprises an implant layer of a second conductivity type arranged between the first and second semiconductor layers of the first conductivity type.

8. The method of claim 1 wherein the bias source comprises a bias voltage source and wherein application of a bias voltage from the bias voltage source to the conductive layer produces an electric field across the plurality of photosensitive elements that facilitates charge carrier collection and thereby provides improved quantum efficiency.

9. The method of claim 1 wherein the sensor layer is formed from a silicon-on-insulator (SOI) wafer.

10. The method of claim 9 wherein the circuit layer is formed in a separate wafer that is bonded to the SOI wafer used to form the sensor layer.

11. An image sensor having a pixel array configured for backside illumination, comprising:
a sensor layer comprising a plurality of photosensitive elements of the pixel array;
a circuit layer comprising circuitry associated with the pixel array;
a conductive layer formed on a backside surface of the sensor layer; and
one or more conductive contacts configured to couple the conductive layer to a bias source in the circuit layer.

12. The image sensor of claim 11 wherein the conductive layer comprises a transparent conductive film.

13. The image sensor of claim 12 wherein the transparent conductive film is patterned to comprise an array of interconnected conductive elements overlying respective ones of the photosensitive elements of the pixel array.

14. The image sensor of claim 13 wherein the conductive elements each have a quadrilateral shape in a plan view and are arranged in rows and columns, with the conductive elements of a given one of the rows being interconnected with one another and with a column conductor that is common to all of the rows.

15. The image sensor of claim 12 wherein the transparent conductive film comprises a combination of indium, tin and oxide.

16. The image sensor of claim 11 wherein the conductive layer comprises a first semiconductor layer of a first conductivity type.

17. The image sensor of claim 16 further comprising a second semiconductor layer of the first conductivity type arranged on a frontside surface of the sensor layer wherein the sensor layer further comprises an implant layer of a second conductivity type arranged between the first and second semiconductor layers of the first conductivity type.

18. The image sensor of claim 11 wherein the bias source comprises a bias voltage source and wherein application of a bias voltage from the bias voltage source to the conductive layer produces an electric field across the plurality of photosensitive elements that facilitates charge carrier collection and thereby provides improved quantum efficiency.

19. A digital imaging device comprising:
an image sensor having a pixel array configured for backside illumination; and
one or more processing elements configured to process outputs of the image sensor to generate a digital image;
wherein said image sensor comprises:
a sensor layer comprising a plurality of photosensitive elements of the pixel array;
a circuit layer comprising circuitry associated with the pixel array;
a conductive layer formed on a backside surface of the sensor layer; and
one or more conductive contacts configured to couple the conductive layer to a bias source in the circuit layer.

20. The digital imaging device of claim 19 wherein said imaging device comprises a digital camera.
